(19) United States
(12) Patent Application Publication
(10) Pub. No.: US 2025/0036844 A1
(43) Pub. Date: Jan. 30, 2025

(54) INTEGRATED CIRCUIT DESIGN METHOD AND SYSTEM

(71) Applicant: TAIWAN SEMICONDUCTOR MANUFACTURING COMPANY, LTD, Hsinchu (TW)

(72) Inventors: Chung-Chieh YANG, Hsinchu (TW); Ming-Yih WANG, Hisnchu (TW)

(21) Appl. No.: 18/359,128

(22) Filed: Jul. 26, 2023

(51) Int. Cl. G06F 30/392; G06F 30/367

(52) U.S. Cl. CPC G06F 30/392; G06F 30/367

(57) ABSTRACT

A method includes identifying one or more locations of a time-dependent dielectric breakdown (TDDB) failure mechanism in an integrated circuit (IC) cell, wherein each location of the one or more locations includes first and second conductor features separated by a dielectric region, identifying first and second nets including the respective first and second conductor features, for each location of the one or more locations, calculating a corresponding failure-in-time (FIT) rate of a corresponding one or more FIT rates based on respective first and second voltage signals of the first and second nets, calculating a total FIT rate based on the one or more FIT rates, and based on the total FIT rate, either modifying the IC cell or storing the IC cell in a storage.

### BACKGROUND

The ongoing trend in miniaturizing integrated circuits (ICs) has resulted in progressively smaller devices which consume less power, yet provide more functionality at higher speeds than earlier technologies. Miniaturization has been achieved through design and manufacturing innovations tied to increasingly strict specifications. Various electronic design automation (EDA) tools are used to generate, revise, and verify designs for semiconductor devices while ensuring that design and manufacturing specifications are met.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 depicts an IC design flow, in accordance with some embodiments.

FIGS. 2A and 2B depict a schematic diagram and corresponding IC layout diagram, in accordance with some embodiments.

FIGS. 3A and 3B depict a schematic diagram and corresponding IC layout diagram, in accordance with some embodiments.

FIGS. 4A-4E depict IC design flows, in accordance with some embodiments.

FIG. 5 depicts a FIT analyzer, in accordance with some embodiments.

FIG. 6 depicts a FIT analyzer, in accordance with some embodiments.

FIGS. 7A-7C depict IC layout diagrams, in accordance with some embodiments.

FIG. 8 depicts an IC design flow, in accordance with some embodiments.

FIG. 9A is a flowchart of a method of generating an IC layout diagram, in accordance with some embodiments.

FIG. 9B is a flowchart of a method of generating an IC layout diagram, in accordance with some embodiments.

FIG. 10 is a block diagram of an IC design system, in accordance with some embodiments.

FIG. 11 is a block diagram of an IC manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, a system and method are directed to identifying one or more locations of one or more time-dependent dielectric breakdown (TDDB) failure mechanisms in one or more IC cells, e.g., an IC layout diagram representing a chip or a portion of a chip, referred to as an IP in some embodiments. A location includes first and second conductor features separated by a dielectric region, the first and second conductor features being included in respective first and second nets of the IC corresponding to the cell or layout diagram. A failure-in-time (FIT) rate is calculated for each location based on first and second voltage signals of the first and second nets, and in some embodiments a temperature, a total FIT rate is calculated based on the FIT rates of each location, and a design activity, e.g., a cell modification or replacement, is performed based on the total FIT rate and/or a FIT rate of a specific location.

By calculating FIT rates using netlist-specific operational conditions, overall FIT rate accuracy is capable of being improved compared to other approaches, e.g., FIT rate calculations based on empirical rating factors and/or direct current (DC)-only methodology.

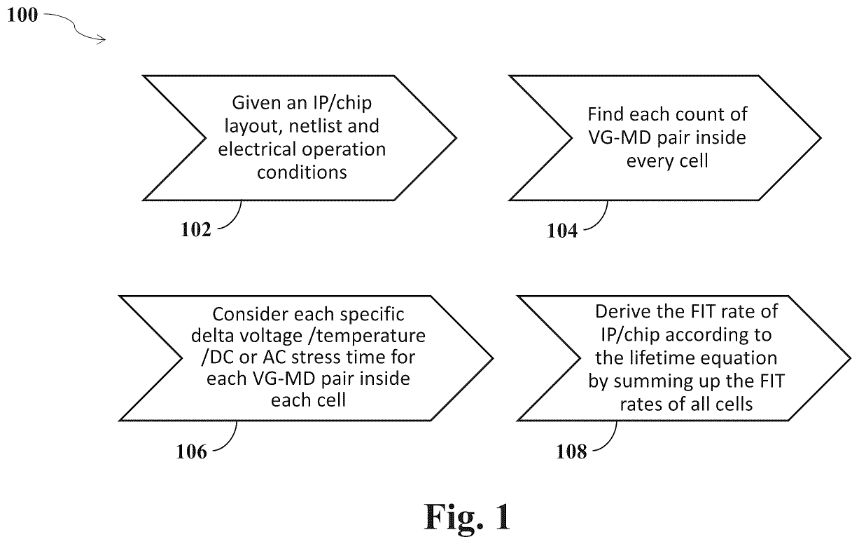

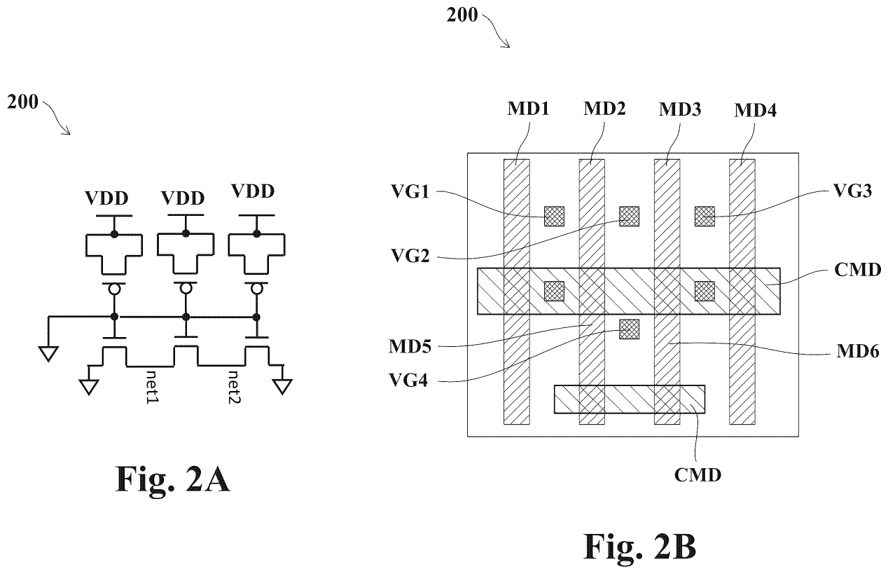

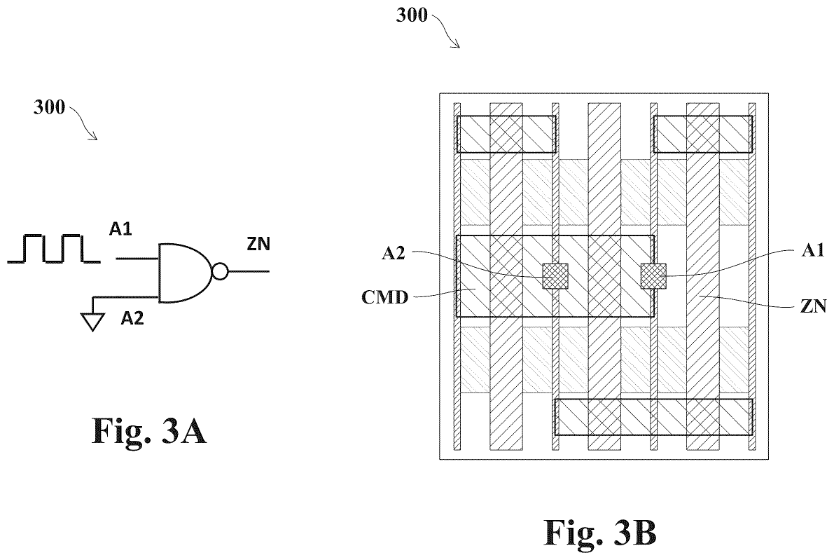

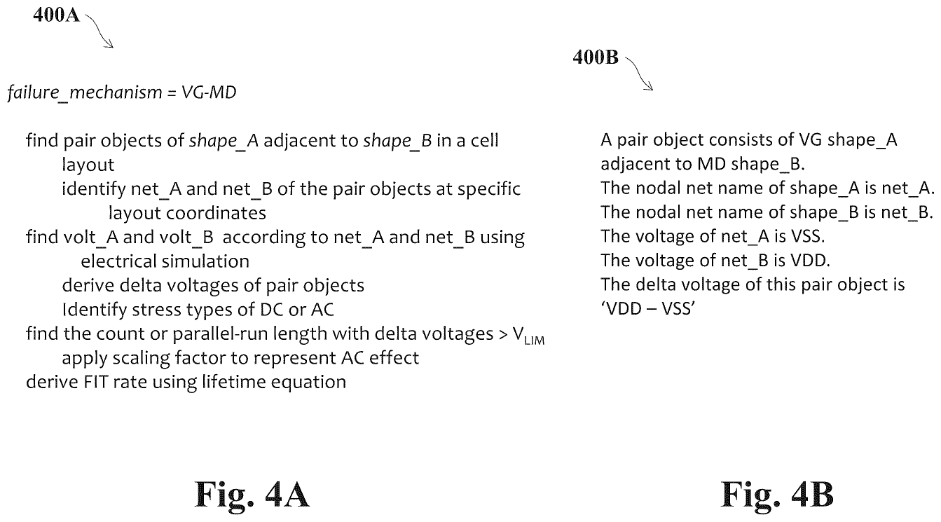

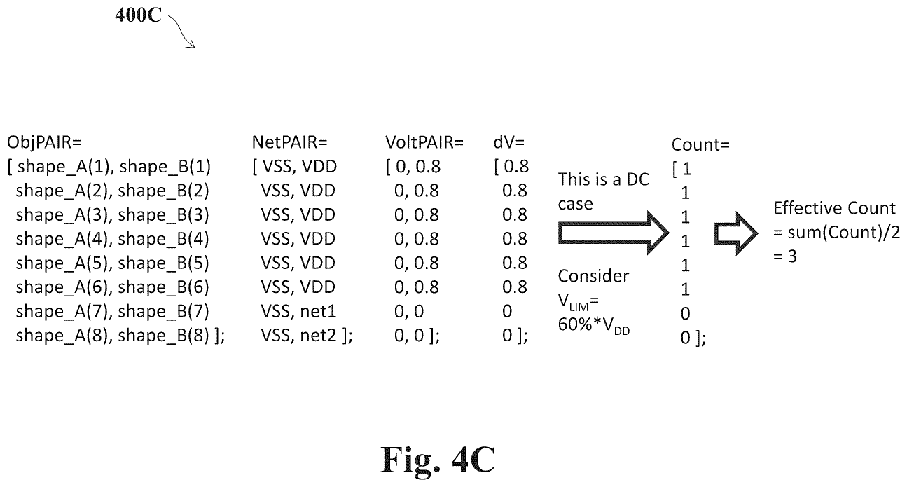

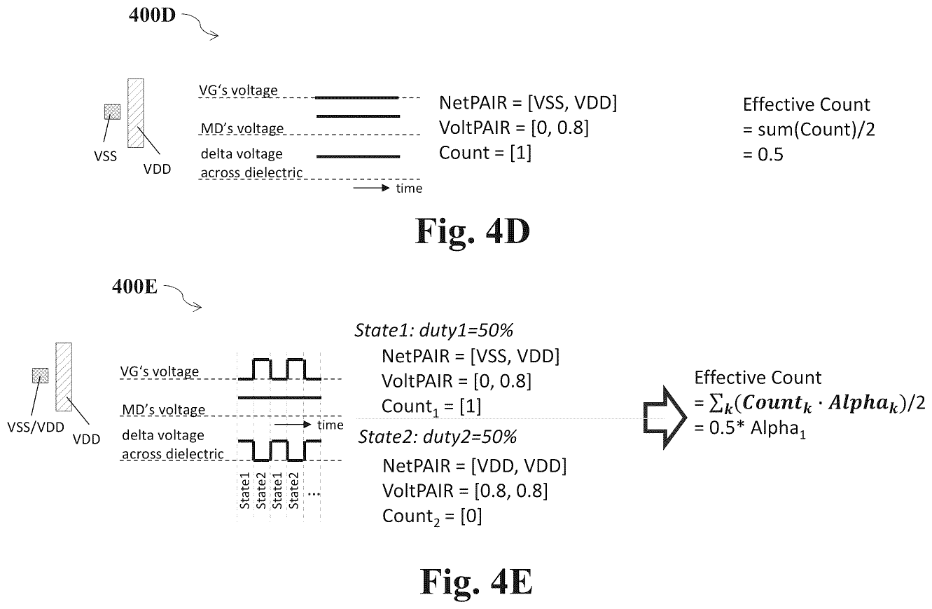

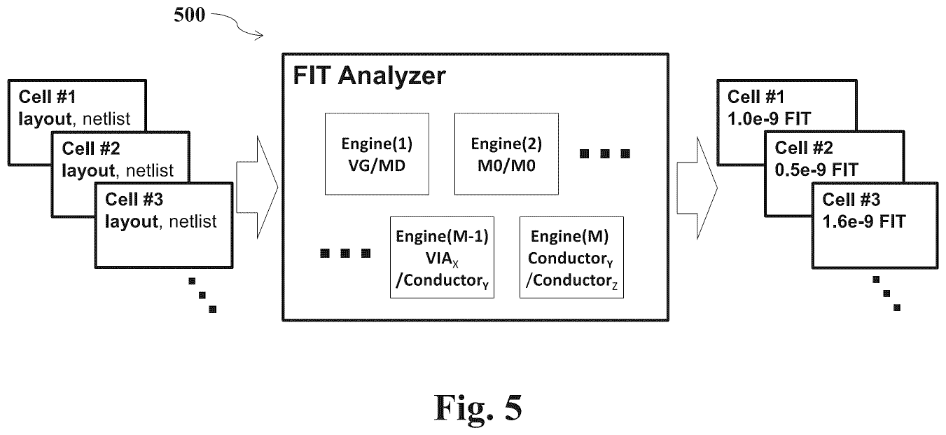

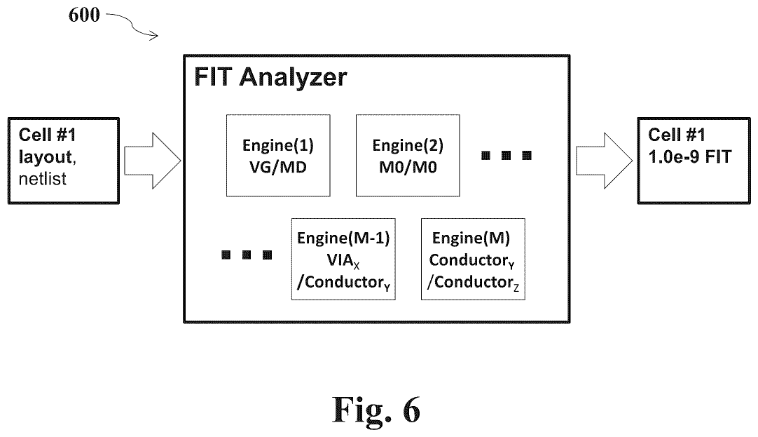

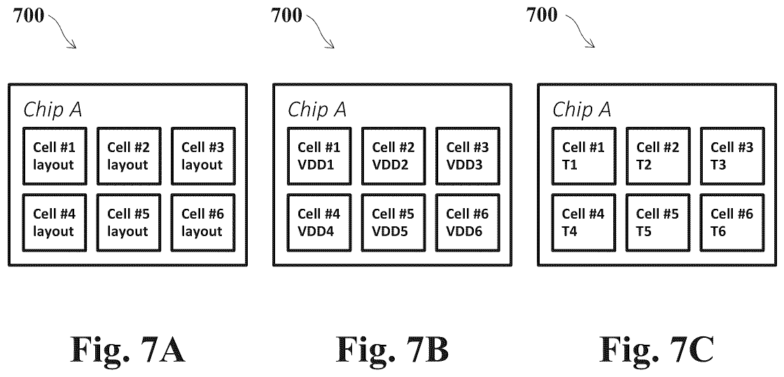

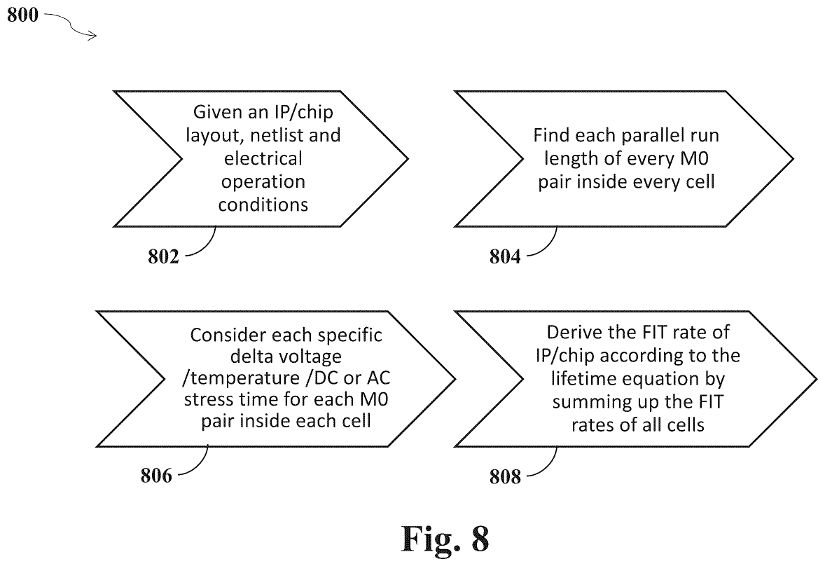

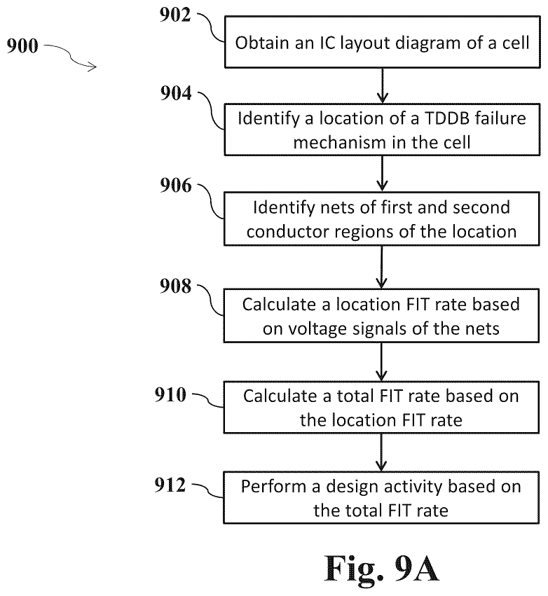

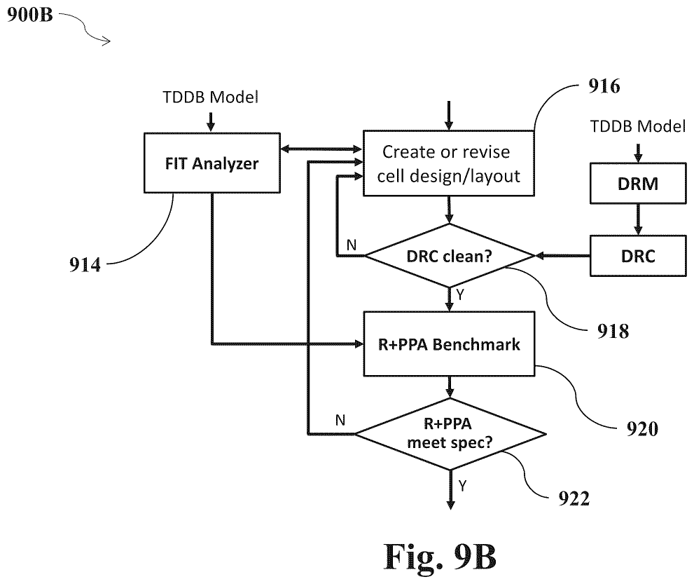

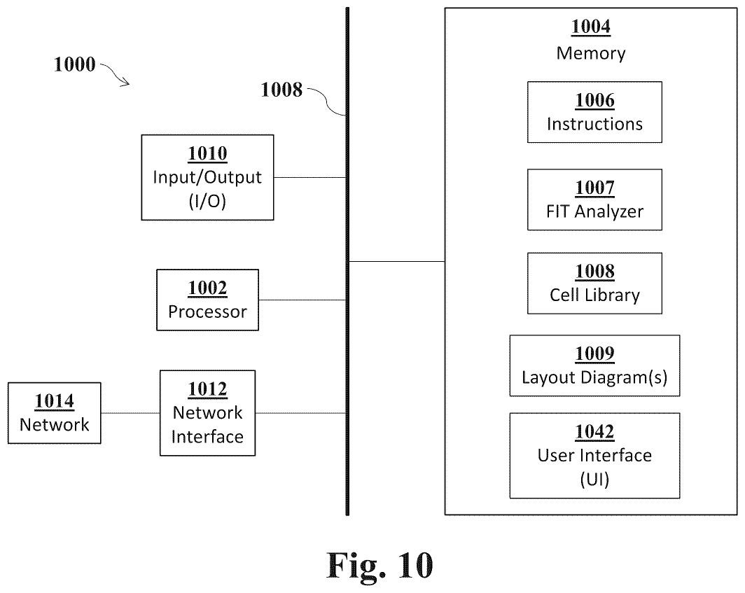

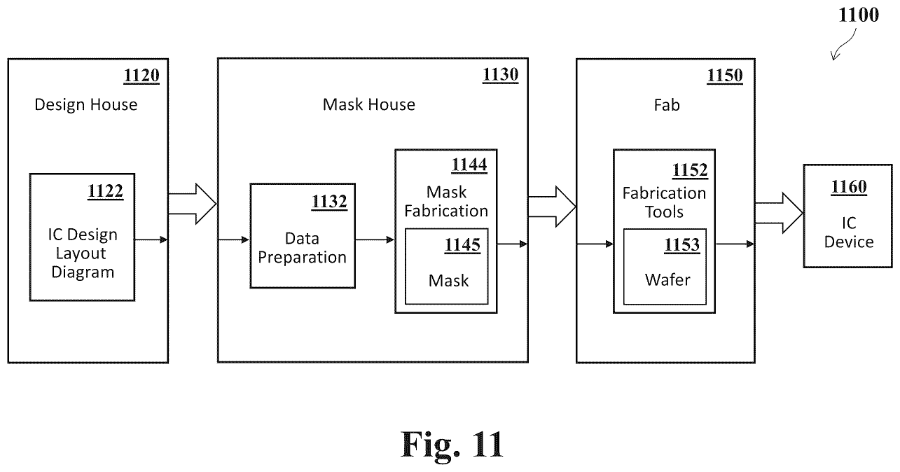

In accordance with various embodiments, as discussed below, FIG. 1 depicts a non-limiting example of an IC design flow, FIGS. 2A-3B depict illustrative examples of schematic diagrams and corresponding IC layout diagrams, FIGS. 4A-4E depict non-limiting examples of IC design flow, FIGS. 5 and 6 depict non-limiting examples of a FIT analyzer, FIGS. 7A-7C depict non-limiting example IC layout diagrams, FIG. 8 depicts a non-limiting example of an IC design flow, FIGS. 9A and 9B are flowcharts of methods 900A and 900B of generating an IC layout diagram, FIG. 10 is a block diagram of an IC design system 1000, e.g., an EDA system 1000, configured to perform some or all of the operations of methods 900A and/or 900B, and FIG. 11 is a block diagram of an IC manufacturing system and associated IC manufacturing flow 1100 by which one or more IC structures are manufactured based at least in part on methods 900A and/or 900B.

Each of the IC layout diagrams discussed below is simplified for the purpose of illustration. In various embodiments, a given IC layout diagram includes one or more features, e.g., active regions, source/drain (S/D) structures, isolation features, internal routing elements, or the like, that are not depicted for the purpose of clarity.

A TDDB failure mechanism generally refers to a time-dependent phenomenon in which a region of one or more initially non-conductive dielectric materials responds to an applied electric field by exhibiting a significant increase in conductivity through one or both of a gradual or a sudden process. One or more threshold conductivity levels can be used to define reliability failure levels depending on overall design considerations of an IC.

Locations at which TDDB failure mechanisms are capable of impacting the reliability of an IC include pairs of conductor features, e.g., polysilicon and/or metal, e.g., copper, gate electrodes, metal lines and/or vias, S/D structures, metal-like defined (MD) segments, and the like, separated by a dielectric region. A location can be considered as a possible TDDB failure mechanism location based on electric fields corresponding to combinations of separation distance and potential voltage differences between the conductor features. In some embodiments, a location is considered to be a TDDB failure mechanism location only if a maximum potential voltage level, e.g., a power supply level of the IC, divided by the separation distance corresponds to an electric field strength above a threshold field strength.

For a given dielectric region, e.g., an intermetal dielectric (IMD) layer or interlevel dielectric (ILD) layer, of a manufacturing process, an operational lifetime can be defined as a function of technology dependent factors, operating conditions including electric field and temperature levels, and a FIT rate. Accordingly, for a given dielectric region, a FIT rate can be defined as a function of the operational lifetime, technology dependent factors, and operating conditions. In some embodiments, one or more relationships between FIT rate and operational lifetime are referred to as a lifetime equation, a TDDB reliability model, or a TDDB model.

FIG. 1 is a flowchart of an IC design flow 100, in accordance with some embodiments. IC design flow 100 including operations 102-108 is a non-limiting example based on pairs of conductor features including a gate via (VG) separated from an MD segment by a dielectric region. IC design flow 100 is provided for the purpose of illustrating a top-level design flow and corresponds to performing some or all of the operations of method 900A and/or 900B discussed below.

At operation 102, an IP/chip layout, netlist, and electrical operation conditions are received. In some embodiments, receiving the electrical operation conditions includes receiving temperature operation conditions.

At operation 104, for each cell in the IP/chip layout, a count of VG-MD pairs is determined.

At operation 106, for each VG-MD pair in each cell determined in operation 104, a FIT rate is calculated by considering one or more voltage differences (delta voltage), temperature, and DC or alternating current (AC) stress times.

At operation 108, a FIT rate of the IP/chip is derived according to the lifetime equation by performing a summing operation on the FIT rates of all the VG-MD pair locations of all the cells.

FIGS. 2A and 2B depict a schematic diagram 200 and corresponding IC layout diagram 200, in accordance with some embodiments. Schematic diagram 200 and IC layout diagram 200 correspond to an IC cell 200 configured as a decoupling capacitor, also referred to as a DCAP cell 200 in some embodiments, in which individual transistors are not labeled for the purpose of clarity.

As depicted in FIG. 2A, DCAP cell 200 includes three PMOS transistors configured to receive a voltage VDD and three NMOS transistors, two of which are configured to receive a voltage VSS indicated by the ground symbol. Gates of each of the transistors are configured to receive voltage VSS. Nets net1 and net2 correspond to shared S/D terminals of the NMOS transistors.

As depicted in FIG. 2B, DCAP cell 200 includes MD segments MD1-MD6, gate vias VG1-VG4, and two instances of cut-MD region CMD. Additional features, e.g., gates underlying gate vias VG1-VG4 and S/D structures underlying MD segments MD1-MD6, of DCAP cell 200 are not depicted for the purpose of clarity.

A gate via VG, e.g., a gate via VG1-VG4, is a region in an IC layout diagram that at least partially defines a via structure in an IC device manufactured based on the IC layout diagram. An MD segment, e.g., an MD segment MD1-MD6, is a region in the IC layout diagram that at least partially defines an MD segment in the IC device manufactured based on the IC layout diagram. A cut-metal region CMD is a region in the IC layout diagram that defines portions of previously formed MD segments that are removed from the IC device manufactured based on the IC layout diagram, thereby forming separate, electrically isolated MD segments.

In the embodiment depicted in FIG. 2B, in operation, each of MD segments MD1-MD4 is configured to receive voltage VDD, MD segment MD5 is included in net net1, MD segment MD6 is included in net net2, and each of gate vias VG1-VG4 is configured to receive voltage VSS. By the configuration depicted in FIG. 2A, each of nets net1 and net2, and thereby MD segments MD5 and MD 6, receives voltage VSS, in operation.

DCAP cell 200 includes first through fourth locations at which respective gate vias VG1-VG4 are paired with corresponding MD segments MD1/MD2, MD2/MD3, MD3/MD4, and MD5/MD6. Two additional instances of gate via VG (not labeled) are located within an instance of cut-MD region CMD and thereby not paired with a corresponding conductor feature.

Based on the operational voltages VDD and VSS of DCAP cell 200, each of the first through third locations at gate vias VG1-VG3 corresponds to a DC voltage difference equal to VDD (VDD-VSS), and the fourth location at gate via VG4 corresponds to a voltage difference equal to zero (VSS-VSS).

Based on a lifetime equation and voltage difference of VDD, each of the first through third locations has a same VG-MD pair FIT rate, e.g. 1e-9 failures over a predetermined lifetime (per unit of time). Based on a voltage difference of zero, the fourth location has a FIT rate of zero.

As a non-limiting example, a total FIT rate of DCAP cell 200 is thereby equal to a sum of the FIT rates at each location, three times the VG-MD FIT rate, e.g., 3e-9 failures per unit of time.

In the discussion above, each of gate vias VG1-VG4 is considered to correspond to a single location of a VG-MD failure location based on a symmetrical arrangement with two corresponding adjacent MD segments. In some embodiments, each of gate vias VG1-VG4 corresponds to two failure locations such that DCAP cell 200 includes a total of eight VG-MD TDDB failure mechanism locations, referred to as VG-MD pair objects in some embodiments, respectively: VG1/MD1, VG1/MD2, VG2/MD2, VG2/MD3, VG3/MD3, VG3/MD4, VG4/MD5, and VG4/MD6. In such embodiments, calculation of the total FIT rate of DCAP cell 200 is analogous to the calculation discussed above and is discussed below with respect to FIG. 4C.

Because the individual FIT rates used to calculate the total FIT rate of DCAP cell 200 are based on actual stress conditions, the total FIT rate is more accurate than total FIT rates calculated without considering actual stress conditions, e.g., an approach in which each of the first through fourth locations is considered to receive the maximum voltage difference of VDD and an empirically determined derating factor, e.g., 0.5, is applied to each individual FIT rate.

FIGS. 3A and 3B depict a schematic diagram 300 and corresponding IC layout diagram 300, in accordance with some embodiments. Schematic diagram 300 and IC layout diagram 300 correspond to an IC cell 300 configured as a NAND gate, also referred to as a NAND cell 300 in some embodiments, in which individual transistors are not labeled for the purpose of clarity.

As depicted in FIG. 3A, NAND cell 300 includes a NAND gate including an input terminal A1 configured to receive an AC voltage signal, an input terminal A2 configured to receive voltage VSS, and an output terminal ZN.

As depicted in FIG. 3B, NAND cell 300 includes gate vias A1 and A2 corresponding to input terminals A1 and A2, MD segment ZN corresponding to output terminal ZN, and four instances of cut-MD region CMD (a single one labeled for clarity). Additional features of NAND cell 300 are not depicted or labeled for the purpose of clarity.

Because gate via A2 is located within an instance of cut-MD region CMD, gate via A2 does not correspond to a VG-MD TDDB failure location, and gate region A1 adjacent to MD segment ZN corresponds to a single (one-sided) VG-MD TDDB failure location in NAND cell 300.

In the embodiment depicted in FIGS. 3A and 3B, in operation, the AC signal received at input terminal A1 alternates between voltages VSS and VDD and has a 50% duty cycle. Based on input terminal A2 receiving voltage VSS, output terminal/MD segment ZN has voltage VDD.

During periods when the AC signal has voltage VSS, the failure location at gate via A1 has a stress equal to VDD (VDD-VSS). During periods when the AC signal has voltage VDD, the failure location at gate via A1 has a stress equal to zero (VDD-VDD).

Based on a lifetime equation, voltage difference of VDD, and duty cycle of 0.5, an initial VG-MD pair FIT rate can be calculated for the failure location. The initial FIT rate is adjusted through multiplication with an AC scaling factor based on stress reduction compared to a DC voltage stress.

The stress reduction and resultant AC scaling factor are based on a recovery effect during the periods of zero stress. In some embodiments, an AC scaling factor has a value corresponding to a duty cycle of an AC signal. In some embodiments, an AC scaling factor is equal to 0.1 or less.

Because the failure location FIT rate and corresponding total FIT rate of NAND cell 300 are based on actual AC stress conditions, the total FIT rate is more accurate than total FIT rates calculated without considering actual AC stress conditions, e.g., an approach in which an AC scaling factor is not applied.

FIGS. 4A-4E depict IC design flows 400A-400E, in accordance with some embodiments. Each of IC design flows 400A-400E is a non-limiting example provided for the purpose of illustration.

As depicted in FIG. 4A, IC design flow 400A is directed to calculating FIT rates at locations corresponding to VG-MD pair objects in which a conductor feature shape-A (VG) is adjacent to a conductor feature shape_B (MD). Conductor features shape_A and shape-B are included in nets net_A and net_B and have voltages volt_A and volt_B obtained by performing an electrical simulation on an IC including the corresponding cell layout. In some embodiments, conductor feature shape_A is one of gate vias VG1-VG4 or A1 and conductor feature shape-B is a corresponding one of MD regions MD1-MD6 or ZN discussed above.

As depicted in FIG. 4B, IC design flow 400B is directed to calculating a FIT rate at one of the locations identified in IC design flow 400A in which net_A, and thereby conductor feature shape_A, has voltage volt_A equal to VSS and net_B, and thereby conductor feature shape_B, has voltage volt_B equal to VDD. A voltage difference (delta voltage) of VDD-VSS is applied to derive the FIT rate at the location. In some embodiments, conductor feature shape_A is one of gate vias VG1-VG3 and conductor feature shape-B is a corresponding one of MD regions MD1-MD4 discussed above.

As depicted in FIG. 4C, IC design flow 400C is directed to calculating FIT rates at first through eighth locations corresponding to VG-MD pair objects, as discussed above with respect to FIGS. 2A and 2B, in which DC voltage VSS is equal to zero and DC voltage VDD is equal to 0.8 V. At the first through sixth locations, the voltage difference (dV) is equal to 0.8 V, and at the seventh and eighth locations, the voltage difference is equal to zero.

Based on a stress voltage threshold VLIM of 60% of VDD, each of the first through sixth locations is assigned a count of one and each of the seventh and eighth locations is assigned a count of zero. Because each location corresponds to one of two sides, an initial count of six is divided by two to get an effective count of three applied to derive the cell, e.g., DCAP cell 200, FIT rate.

Equation 1 presented below is a non-limiting example of a lifetime equation usable to derive a FIT rate based on a specific failure mechanism lifetime:

$$Lifetime = {τ}_{0} \times exp ( - γ \sqrt{E} ) \times {( L )}^{- 1 / β area} \times exp ( \frac{{E}_{a}}{kT} ) \times exp ( \frac{1}{β} * ln ( - ln ( 1 - F ) ) ) \qquad ( 1 )$$

In equation 1, lifetime is a cell, IP, or chip operation time, e.g., 10 years or 87,600 hours; E is the electrical field based on the voltage stress and separation distance between the adjacent conductor features; L is the effective count (or a parallel-run length in cases in which adjacent conductor features are coextensive); k is Boltzmann's constant; τ is the absolute operating temperature; τₒ, γ, βₐᵣₑₐ, Eₐ, and β are technology dependent coefficients obtained from one or both of measurement data or a model forecast; and F is the number of failures during the lifetime. F can be converted to FIT (Failures in Time) rate by F/lifetime * 1e9, where the units of lifetime and 1e9 are both hours. The FIT rate of a device implies the number of failures that can be expected in one billion (1e9) device-hours of operation.

By inputting one or more voltage stress-derived electric field values, and one or more temperatures in some embodiments, along with the other input parameters into a lifetime equation, e.g., equation 1, a FIT rate as function of F can be calculated based on a simulation of actual operating conditions.

As depicted in FIG. 4D, IC design flow 400D is directed to calculating a FIT rate at a VG-MD location based on a DC voltage stress (delta voltage). As discussed above with respect to FIG. 4C, the effective count is obtained by dividing an initial count by two to reflect the FIT corresponding to one of two sides.

As depicted in FIG. 4E, IC design flow 400E is directed to calculating a FIT rate at a VG-MD location based on an AC voltage stress (delta voltage). In the embodiment depicted in FIG. 4E the VG voltage has an AC signal with a 50% duty cycle between voltages VSS and VDD, and the MD voltage has the DC voltage VDD. The voltage stress is divided into a state State1 in which the voltage stress is equal to VDD and a state State2 in which the voltage stress is equal to zero, thereby corresponding to a total of two states (having an index number k).

The number of AC signals and corresponding states depicted in FIG. 4E is a non-limiting example provided for the purpose of illustration. In some embodiments, a location has more than one AC signal and/or more than two states.

An initial count is equal to a sum, for each value of the index k, of the count and an AC scaling factor Alpha corresponding to the kth state, and the effective count is obtained by dividing the initial count by two to reflect the FIT corresponding to one of two sides.

From equation 1 above, a proportional relationship between Lifetime and the effective count L is given by equation 2:

$$Lifetime {α ( L )}^{- 1 / β area} \qquad ( 2 )$$

To compensate for the duty cycle and stress recovery phenomenon of a given state of an AC stress, a proportional relationship can be described by equation 3:

$$Lifetime \times \frac{1}{dutyk} \times {S}_{AC} {α ( L \times {Alpha}_{k} )}^{- 1 / β area} \qquad ( 3 )$$

In equation 3, dutyk is the duty cycle of the kth state and SAC is a technology dependent lifetime AC scaling factor obtained from measurement data or a model. Combining equations 2 and 3, a value of Alpha for the kth state is given by:

$${Alpha}_{k} = {( {S}_{AC} / {duty}_{k} )}^{- β area} \qquad ( 4 )$$

IC design flows 400A-400E and the associated equations discussed above are non-limiting examples by which FIT rates can be calculated based on operating conditions. In some embodiments, other IC design flows and parameter relationships are used to calculate FIT rates based on operating conditions.

FIGS. 5 and 6 depict FIT analyzers 500 and 600, in accordance with some embodiments. Each of FIT analyzers 500 and 600 is one or more computer programs configured to execute some or all of method 900A discussed below. In some embodiments, FIT analyzers 500 and 600 are separate or combined FIT analyzers. In some embodiments, one or both of FIT analyzers 500 or 600 corresponds to a FIT analyzer 1007 of IC design system 1000, discussed below with respect to FIG. 10.

As depicted in FIG. 5, FIT analyzer 500 is configured to receive layout and netlist information for each one of multiple cells (three shown for the purpose of illustration), and to calculate a cell FIT rate for each cell, e.g., as discussed above.

FIT analyzer 500 includes multiple design for reliability (DfR) engines Engine (1)-Engine (M), each configured to calculate a FIT rate based on a specific TDDB failure mechanism. In the embodiment depicted in FIG. 5, example engines correspond to VG-MD, first metal (metal zero)-to-first metal (M0-M0), via-to-conductor, and conductor-to-conductor TDDB failure mechanisms. Other types of TDDB failure mechanisms are within the scope of the present disclosure.

In some embodiments, FIT analyzer 500 includes DfR engines Engine (1)-Engine (M) configured to process multiple failure mechanisms in parallel. In some embodiments, one or more of DfR engines Engine (1)-Engine (M) are configured to process multiple cells in parallel.

As depicted in FIG. 6, FIT analyzer 600 is configured to receive layout and netlist information for a given cell, and to calculate the cell FIT rate by performing a summing operation on the FIT rates corresponding to each TDDB failure mechanism.

In a non-limiting example, FIT analyzer 600 performs the summing operation on a total of four failure mechanisms using one of two equations based on FIT rates F1-F4. The first equation corresponds to a case in which all four of the failure mechanisms are uncorrelated, e.g., independent, in which case the total FIT rate Ftotal is given by:

$$Ftotal = F 1 + F 2 + F 3 + F 4 \qquad ( 5 )$$

The second equation corresponds to a case in which the third and fourth failure mechanisms are correlated, e.g., related to one or more common sources, in which case the total FIT rate Ftotal is given by:

$$Ftotal = F 1 + F 2 + \sqrt{F 3 F 4} \qquad ( 6 )$$

FIGS. 7A-7C depict an IC layout diagram 700, in accordance with some embodiments. IC layout diagram 700 corresponds to an IC chip Chip A including cells Cell #1-Cell #6. Cells Cell #1-Cell #6 include cell layouts as depicted in FIG. 7A and are designed to have corresponding operating voltages VDD1-VDD6 as depicted in FIG. 7B and operating temperatures T1-T6 as depicted in FIG. 7C.

In various embodiments, one or more of operating voltages VDD1-VDD6 and/or temperatures T1-T6 have constant operating lifetime levels or multiple constant levels over an operating lifetime of Chip A, e.g., corresponding to multiple operating states of Chip A.

In some embodiments, a total FIT rate of Chip A is calculated by performing a first summing operation on multiple failure mechanisms of each cell to obtain cell FIT rates Fcelln, followed by performing a second summing operation on the cell FIT rates, as illustrated by equation 7:

$$Fchip = {F}_{cell} \#1 + Fcell \#2 + … + Fcell \# N \qquad ( 7 )$$

In some embodiments, calculating one or more of the cell FIT rates Fcelln is a function of the corresponding one or more of VDD1-VDD6 and/or T1-T6.

In some embodiments, a total FIT rate of Chip A is calculated by performing a first summing operation on each cell for each failure mechanisms to obtain failure mechanism FIT rates F1-FM, followed by performing a second summing operation on the failure mechanism FIT rates, as illustrated by equation 8:

$$Fchip = F 1 + F 2 + … + FM \qquad ( 8 )$$

In some embodiments, calculating one or more of the failure mechanism FIT rates F1-FM is a function of one or more of VDD1-VDD6 and/or T1-T6.

Compared to embodiments in which the first summing operation is performed to calculate cell FIT rates, performing the first summing operation to calculate failure mechanism FIT rates provides a less conservative and more realistic result.

FIG. 8 is a flowchart of an IC design flow 800, in accordance with some embodiments. IC design flow 800 including operations 802-808 is a non-limiting example based on pairs of conductor features including adjacent pairs of first metal (M0) conductor features separated from each other by a dielectric region over parallel run lengths. IC design flow 800 is provided for the purpose of illustrating a top-level design flow and corresponds to performing some or all of the operations of method 900A and/or 900B discussed below.

At operation 802, an IP/chip layout, netlist, and electrical operation conditions are received. In some embodiments, receiving the electrical operation conditions includes receiving temperature operation conditions.

At operation 804, for each cell in the IP/chip layout, a parallel run length of each M0 pair is determined.

At operation 806, for each M0 pair in each cell determined in operation 804, a FIT rate is calculated by considering one or more voltage differences (delta voltage), temperature, and DC or alternating current (AC) stress times.

At operation 808, a FIT rate of the IP/chip is derived according to the lifetime equation by performing a summing operation on the FIT rates of all the M0 pair locations of all the cells.

FIG. 9A is a flowchart of method 900A of generating an IC layout diagram, in accordance with some embodiments. In some embodiments, generating the IC layout diagram includes generating some or all of one or more of IC layout diagrams 100, 200, or 700 discussed above with respect to FIGS. 1-8.

In some embodiments, some or all of method 900A is executed by a processor of a computer. In some embodiments, some or all of method 900A is executed by a processor 1002 of IC design system 1000, discussed below with respect to FIG. 10.

Some or all of the operations of method 900A are capable of being performed as part of a design procedure performed in a design house, e.g., a design house 1120 discussed below with respect to FIG. 11.

In some embodiments, the operations of method 900A are performed in the order depicted in FIG. 9A. In some embodiments, the operations of method 900A are performed in an order other than the order depicted in FIG. 9A. In some embodiments, one or more operations are performed before, between, during, and/or after performing one or more operations of method 900A.

In some embodiments, performing some or all of the operations of method 900A corresponds to performing some or all of operation 914 of method 900B discussed below.

At operation 902, an IC layout diagram of a cell is obtained. In some embodiments, obtaining the IC layout diagram includes obtaining the cell being an entirety of the IC layout diagram, e.g., from a cell library. In some embodiments, obtaining the IC layout diagram includes obtaining the IC layout diagram corresponding to an IP or chip including the cell. In some embodiments, obtaining the IC layout diagram includes obtaining the IC layout diagram including the cell being one cell of a plurality of cells of the IC layout diagram.

In some embodiments, obtaining the IC layout diagram includes obtaining one or more of DCAP cell 200 discussed above with respect to FIGS. 2A and 2B, NAND cell 300 discussed above with respect to FIGS. 3A and 3B, or IC layout 700 discussed above with respect to FIGS. 7A-7C.

In some embodiments, obtaining the IC layout diagram includes obtaining a cell from a cell library 1008 or an IC layout diagram 1009 of IC design system 1000, discussed below with respect to FIG. 10.

At operation 904, a location of a TDDB failure mechanism is identified. Identifying the location includes identifying the location including first and second conductor features separated by a dielectric region, e.g., as discussed above with respect to FIGS. 1-8.

In some embodiments, the location is one location of multiple locations in a cell corresponding to the TDDB failure mechanism, and identifying the location includes identifying each of the multiple locations.

In some embodiments, the location is one location of multiple locations in multiple cells corresponding to the TDDB failure mechanism, and identifying the location includes identifying each of the locations in each of the multiple cells.

In some embodiments, the TDDB failure mechanism is one of multiple TDDB failure mechanisms of one or more cells, and identifying the location includes identifying locations of each of the multiple TDDB mechanisms of the one or more cells.

At operation 906, nets of the first and second conductor regions of the location are identified. Identifying the nets of the first and second conductor regions includes accessing one or more netlists of the corresponding cell, IP, and/or chip, e.g., as discussed above with respect to FIGS. 1-8.

At operation 908, a location FIT rate is calculated based on voltage signals of the nets. Calculating the location FIT rate includes obtaining each of the corresponding first and second voltage signals from a simulation of a circuit including the first and second nets, e.g., as discussed above with respect to FIGS. 1-8.

In some embodiments, calculating the location FIT rate includes calculating the FIT rate based on a lifetime equation, e.g., equation 1 discussed above.

In some embodiments, calculating the location FIT rate includes each of the corresponding first and second voltage signals being a DC voltage signal. In some embodiments, calculating the location FIT rate includes assigning a predetermined FIT rate value for a location at which a difference between the corresponding first and second voltage signals has a predetermined non-zero value, e.g., above a threshold, and assigning a FIT rate value of zero for a location at which the difference between the corresponding first and second voltage signals is equal to zero, e.g., below the threshold.

In some embodiments, calculating the location FIT rate includes the corresponding first and second voltage signals including one or more AC voltage signals. In some embodiments, calculating the location FIT rate includes identifying a plurality of AC stress states corresponding to a plurality of voltage levels of an AC voltage signal, assigning a predetermined scaling factor for each AC stress state of the plurality of AC stress states corresponding to a voltage difference between the first and second voltage signals having a non-zero value, and assigning a FIT rate value of zero for each AC stress state of the plurality of AC stress states corresponding to the difference between the corresponding first and second voltage signals having a zero value. In some embodiments, assigning the predetermined scaling factor for each AC stress state of the plurality of AC stress states include assigning a rating factor corresponding to a duty cycle of the AC voltage signal.

In some embodiments, calculating the location FIT rate includes calculating the location FIT rate further based on one or more operational temperatures, e.g., as discussed above with respect to FIGS. 1-8.

At operation 910, a total FIT rate is calculated based on the location FIT rate. Calculating the total FIT rate includes performing one or more summing operations on the location FIT rate as discussed above with respect to FIGS. 1-8.

In some embodiments, performing a summing operation includes summing a term based on a correlation between multiple TDDB failure mechanisms, e.g., as discussed above with respect to FIGS. 7A-7C.

In some embodiments, calculating the total FIT rate includes, for each location of one or more locations, calculating a corresponding FIT rate of a corresponding one or more FIT rates based on respective first and second voltage signals of first and second nets, and calculating a total FIT rate of the IC layout diagram based on the one or more FIT rates of each TDDB failure mechanism of a plurality of TDDB failure mechanisms and each cell of a plurality of cells.

In some embodiments, calculating the total FIT rate includes calculating cell FIT rates by, for each cell of a plurality of cells, performing a first summing operation on each FIT rate of one or more FIT rates of each TDDB failure mechanism of a plurality of TDDB failure mechanisms, and performing a second summing operation on the cell FIT rates corresponding to the plurality of cells. In some embodiments, performing the first summing operation for each cell of the plurality of cells includes calculating the corresponding one or more FIT rates based on one or more of a distribution of voltage levels between cells, a distribution of voltage levels over time, a distribution of temperatures between cells, or a distribution of temperatures over time.

In some embodiments, calculating the total FIT rate includes calculating TDDB failure mechanism FIT rates by, for each TDDB failure mechanism of a plurality of TDDB failure mechanisms, performing a first summing operation on each FIT rate of the one or more FIT rates of each cell of a plurality of cells, and performing a second summing operation on the TDDB failure mechanism FIT rates corresponding to the plurality of TDDB failure mechanisms. In some embodiments, calculating the TDDB failure mechanism FIT rates by performing the first summing operation for each TDDB failure mechanism of the plurality of TDDB failure mechanisms includes calculating the corresponding one or more FIT rates based on one or more of a distribution of voltage levels between cells, a distribution of voltage levels over time, a distribution of temperatures between cells, or a distribution of temperatures over time.

At operation 912, a design activity is performed based on the total FIT rate. In some embodiments, performing the design activity includes modifying a cell or storing a cell, either modified or unmodified, in a storage device, e.g., a cell library such as cell library 1008 discussed below.

In some embodiments, performing the design activity includes modifying an IC layout diagram or storing an IC layout diagram, either modified or unmodified, in a storage device, e.g., as an IC layout diagram 1009 discussed below. In some embodiments, modifying an IC layout diagram includes replacing a cell of the IC layout diagram, e.g., based on a location being identified as a failure location.

In some embodiments, performing the design activity includes identifying failure information corresponding to a location at which a location FIT rate exceeds a threshold level. In some embodiments, failure information includes one or more of failure location coordinates, a TDDB failure mechanism identifier, or net names.

In some embodiments, performing the one or more IC device design operations includes routing one or more metal lines to one or more components of the IC layout diagram.

In some embodiments, performing the design activity includes performing some or all of operations 914-922 of method 900B discussed below.

In some embodiments, performing the design activity includes fabricating at least one of one or more semiconductor masks or at least one component in a layer of a semiconductor IC, or one or more manufacturing operations are performed based on the IC layout diagram. Fabricating one or more semiconductor masks or at least one component in a layer of a semiconductor IC, and performing one or more manufacturing operations, e.g., one or more lithographic exposures, based on a corresponding IC layout diagram are discussed below with respect to FIG. 11.

By executing some or all of the operations of method 900A, FIT rates are calculated using netlist-specific operational conditions whereby overall FIT rate accuracy is capable of being improved compared to other approaches, e.g., FIT rate calculations based on empirical rating factors and/or DC-only methodology.

FIG. 9B is a flowchart of method 900B of generating an IC layout diagram, in accordance with some embodiments. In some embodiments, generating the IC layout diagram includes generating some or all of one or more of IC layout diagrams 100, 200, or 700 discussed above with respect to FIGS. 1-8.

In some embodiments, some or all of method 900B is executed by a processor of a computer. In some embodiments, executing some or all of method 900B is part of executing an automated place-and-route (APR) operation using a processor of a computer. In some embodiments, some or all of method 900B is executed by processor 1002 of IC layout diagram generation system 1000, discussed below with respect to FIG. 10.

In some embodiments, one or more operations of method 900B are a subset of operations of a method of forming an IC device. In some embodiments, one or more operations of method 900B are a subset of operations of an IC manufacturing flow, e.g., the IC manufacturing flow discussed below with respect to manufacturing system 1100 and FIG. 11.

In some embodiments, the operations of method 900B are performed in the order depicted in FIG. 9B. In some embodiments, the operations of method 900B are performed simultaneously and/or in an order other than the order depicted in FIG. 9B. In some embodiments, one or more operations are performed before, between, during, and/or after performing one or more operations of method 900B.

At operation 914, a FIT analyzer is used to receive a TDDB model, e.g., including one or more lifetime equations, and calculate a total FIT rate of an IC layout diagram. In some embodiments, calculating the total FIT rate includes receiving the IC layout diagram by performing operation 916 discussed below.

In some embodiments, calculating the total FIT rate includes deriving FIT rates of cells as a reliability benchmark index, and outputting the reliability benchmark index to a benchmark analyzer.

In some embodiments, using the FIT analyzer includes using one or both of FIT analyzers 500 or 600 discussed above with respect to FIGS. 5 and 6. In some embodiments, using the FIT analyzer includes using FIT analyzer 1007 of IC layout diagram generation system 1000, discussed below with respect to FIG. 10.

In some embodiments, performing operation 914 includes performing some or all of the operations of method 900A discussed above with respect to FIG. 9A.

At operation 916, an IC layout diagram is created or revised. In some embodiments, creating or revising the IC layout diagram includes outputting the IC layout diagram to the FIT analyzer of operation 914.

In some embodiments, creating or revising the IC layout diagram is based on receiving failure location information from the FIT analyzer of operation 914. In some embodiments, revising the IC layout diagram includes modifying or replacing a cell of the IC layout diagram based on the failure location information.

Operation 916 includes outputting the IC layout diagram.

At operation 918, the IC layout diagram is received and a design rule pass/fail determination is made based on the IC layout diagram and a design rule checklist (DRC) obtained from a design rule manual (DRM). If needed, operations 916 and 918 are repeated until the IC layout diagram passes the design rule check.

At operation 920, a benchmark analysis is performed on the IC layout diagram based on the reliability benchmark index received from the FIT analyzer and on power performance, area (PPA) benchmark criteria.

At operation 922, a status determination is made on the IC layout diagram based on the benchmark analysis of operation 920. Operations 914-922 are repeated as needed until the IC layout diagram meets the reliability and PPA criteria, and the IC layout diagram is stored in a storage device, e.g., memory 1004 of system 100 discussed below with respect to FIG. 10.

By executing some or all of the operations of method 900B, an IC layout diagram is generated using TDDB failure criteria based on operational conditions as discussed above, thereby obtaining the benefits discussed above.

FIG. 10 is a block diagram of an electronic design automation (EDA) system 1000 in accordance with some embodiments.

In some embodiments, EDA system 1000 includes an APR system. Methods described herein of designing layout diagrams represent wire routing arrangements, in accordance with one or more embodiments, are implementable, for example, using EDA system 1000, in accordance with some embodiments.

In some embodiments, EDA system 1000 is a general purpose computing device including a hardware processor 1002 and a non-transitory, computer-readable storage medium 1004. Storage medium 1004, amongst other things, is encoded with, i.e., stores, computer program code 1006 and FIT analyzer 1007, i.e., one or more sets of executable instructions. Execution of instructions 1006 and FIT analyzer 1007 by hardware processor 1002 represents (at least in part) an EDA tool which implements a portion or all of the methods described herein in accordance with one or more embodiments (hereinafter, the noted processes and/or methods).

Processor 1002 is electrically coupled to computer-readable storage medium 1004 via a bus 1008. Processor 1002 is also electrically coupled to an I/O interface 1010 by bus 1008. A network interface 1012 is also electrically connected to processor 1002 via bus 1008. Network interface 1012 is connected to a network 1014, so that processor 1002 and computer-readable storage medium 1004 are capable of connecting to external elements via network 1014. Processor 1002 is configured to execute computer program code 1006 encoded in computer-readable storage medium 1004 in order to cause system 1000 to be usable for performing a portion or all of the noted processes and/or methods. In one or more embodiments, processor 1002 is a central processing unit (CPU), a multi-processor, a distributed processing system, an application specific integrated circuit (ASIC), and/or a suitable processing unit.

In one or more embodiments, computer-readable storage medium 1004 is an electronic, magnetic, optical, electromagnetic, infrared, and/or a semiconductor system (or apparatus or device). For example, computer-readable storage medium 1004 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 1004 includes a compact disk-read only memory (CD-ROM), a compact disk-read/write (CD-R/W), and/or a digital video disc (DVD).

In one or more embodiments, storage medium 1004 stores computer program code 1006 configured to cause system 1000 (where such execution represents (at least in part) the EDA tool) to be usable for performing a portion or all of the noted processes and/or methods. In one or more embodiments, storage medium 1004 also stores information which facilitates performing a portion or all of the noted processes and/or methods. In one or more embodiments, storage medium 1004 stores cell library 1008 of IC layout cells including one or more of cells 100 or 200 as disclosed herein. In one or more embodiments, storage medium 1004 stores one or more layout diagrams 1009 corresponding to one or more layouts disclosed herein, e.g., IC layout diagram 700 discussed above.

EDA system 1000 includes I/O interface 1010. I/O interface 1010 is coupled to external circuitry. In one or more embodiments, I/O interface 1010 includes a keyboard, keypad, mouse, trackball, trackpad, touchscreen, and/or cursor direction keys for communicating information and commands to processor 1002.

EDA system 1000 also includes network interface 1012 coupled to processor 1002. Network interface 1012 allows system 1000 to communicate with network 1014, to which one or more other computer systems are connected. Network interface 1012 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 1000.

System 1000 is configured to receive information through I/O interface 1010. The information received through I/O interface 1010 includes one or more of instructions, data, design rules, libraries of standard cells, and/or other parameters for processing by processor 1002. The information is transferred to processor 1002 via bus 1008. EDA system 1000 is configured to receive information related to a user interface (UI) through I/O interface 1010. The information is stored in computer-readable medium 1004 as UI 1042.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 1000. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 11 is a block diagram of an integrated circuit (IC) manufacturing system 1100, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 1100.

In FIG. 11, IC manufacturing system 1100 includes entities, such as a design house 1120, a mask house 1130, and an IC manufacturer/fabricator (fab) 1150, that interact with one another in the design, development, and manufacturing cycles and/or services related to manufacturing an IC device 1160. The entities in system 1100 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1120, mask house 1130, and IC fab 1150 is owned by a single larger company. In some embodiments, two or more of design house 1120, mask house 1130, and IC fab 1150 coexist in a common facility and use common resources.

Design house (or design team) 1120 generates an IC design layout diagram 1122. e.g., including one or more of IC layout diagrams 100, 200, or 700 discussed above with respect to FIGS. 1-9B. IC design layout diagram 1122 includes various geometrical patterns designed for an IC device 1160. The geometrical patterns correspond to patterns of metal, oxide, or semiconductor layers that make up the various components of IC device 1160 to be fabricated. The various layers combine to form various IC features. For example, a portion of IC design layout diagram 1122 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1120 implements a proper design procedure to form IC design layout diagram 1122. The design procedure includes one or more of logic design, physical design or place and route. IC design layout diagram 1122 is presented in one or more data files having information of the geometrical patterns. For example, IC design layout diagram 1122 can be expressed in a GDSII file format or DFII file format.

Mask house 1130 includes data preparation 1132 and mask fabrication 1144. Mask house 1130 uses IC design layout diagram 1122 to manufacture one or more masks 1145 to be used for fabricating the various layers of IC device 1160 according to IC design layout diagram 1122. Mask house 1130 performs mask data preparation 1132, where IC design layout diagram 1122 is translated into a representative data file (RDF). Mask data preparation 1132 provides the RDF to mask fabrication 1144. Mask fabrication 1144 includes a mask writer. A mask writer converts the RDF to an image on a substrate, such as a mask (reticle) 1145 or a semiconductor wafer 1153. The design layout diagram 1122 is manipulated by mask data preparation 1132 to comply with particular characteristics of the mask writer and/or requirements of IC fab 1150. In FIG. 11, mask data preparation 1132 and mask fabrication 1144 are illustrated as separate elements. In some embodiments, mask data preparation 1132 and mask fabrication 1144 can be collectively referred to as mask data preparation.

In some embodiments, mask data preparation 1132 includes optical proximity correction (OPC) which uses lithography enhancement techniques to compensate for image errors, such as those that can arise from diffraction, interference, other process effects and the like. OPC adjusts IC design layout diagram 1122. In some embodiments, mask data preparation 1132 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1132 includes a mask rule checker (MRC) that checks the IC design layout diagram 1122 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1122 to compensate for photolithographic implementation effects during mask fabrication 1144, which may undo part of the modifications performed by OPC in order to meet mask creation rules.

In some embodiments, mask data preparation 1132 includes lithography process checking (LPC) that simulates processing that will be implemented by IC fab 1150 to fabricate IC device 1160. LPC simulates this processing based on IC design layout diagram 1122 to create a simulated manufactured device, such as IC device 1160. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1122.

It should be understood that the above description of mask data preparation 1132 has been simplified for the purposes of clarity. In some embodiments, data preparation 1132 includes additional features such as a logic operation (LOP) to modify the IC design layout diagram 1122 according to manufacturing rules. Additionally, the processes applied to IC design layout diagram 1122 during data preparation 1132 may be executed in a variety of different orders.

After mask data preparation 1132 and during mask fabrication 1144, a mask 1145 or a group of masks 1145 are fabricated based on the modified IC design layout diagram 1122. In some embodiments, mask fabrication 1144 includes performing one or more lithographic exposures based on IC design layout diagram 1122. In some embodiments, an electron-beam (e-beam) or a mechanism of multiple e-beams is used to form a pattern on a mask (photomask or reticle) 1145 based on the modified IC design layout diagram 1122. Mask 1145 can be formed in various technologies. In some embodiments, mask 1145 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1145 includes a transparent substrate (e.g., fused quartz) and an opaque material (e.g., chromium) coated in the opaque regions of the binary mask. In another example, mask 1145 is formed using a phase shift technology. In a phase shift mask (PSM) version of mask 1145, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1144 is used in a variety of processes. For example, such a mask(s) is used in an ion implantation process to form various doped regions in semiconductor wafer 1153, in an etching process to form various etching regions in semiconductor wafer 1153, and/or in other suitable processes.

IC fab 1150 is an IC fabrication business that includes one or more manufacturing facilities for the fabrication of a variety of different IC products. In some embodiments, IC Fab 1150 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1150 includes fabrication tools 1152 configured to execute various manufacturing operations on semiconductor wafer 1153 such that IC device 1160 is fabricated in accordance with the mask(s), e.g., mask 1145. In various embodiments, fabrication tools 1152 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1150 uses mask(s) 1145 fabricated by mask house 1130 to fabricate IC device 1160. Thus, IC fab 1150 at least indirectly uses IC design layout diagram 1122 to fabricate IC device 1160. In some embodiments, semiconductor wafer 1153 is fabricated by IC fab 1150 using mask(s) 1145 to form IC device 1160. In some embodiments, the IC fabrication includes performing one or more lithographic exposures based at least indirectly on IC design layout diagram 1122. Semiconductor wafer 1153 includes a silicon substrate or other proper substrate having material layers formed thereon. Semiconductor wafer 1153 further includes one or more of various doped regions, dielectric features, multilevel interconnects, and the like (formed at subsequent manufacturing steps).

In some embodiments, a method includes identifying one or more locations of a TDDB failure mechanism in an IC cell, wherein each location of the one or more locations includes first and second conductor features separated by a dielectric region, identifying first and second nets including the respective first and second conductor features, for each location of the one or more locations, calculating a corresponding FIT rate of a corresponding one or more FIT rates based on respective first and second voltage signals of the first and second nets, calculating a total FIT rate based on the one or more FIT rates, and based on the total FIT rate, either modifying the IC cell or storing the IC cell in a storage device. In some embodiments, calculating each FIT rate of the one or more FIT rates includes obtaining each of the corresponding first and second voltage signals from a simulation of a circuit comprising the first and second nets. In some embodiments, calculating each FIT rate of the one or more FIT rates includes each of the corresponding first and second voltage signals being a DC voltage signal. In some embodiments, calculating each FIT rate of the one or more FIT rates includes assigning a predetermined FIT rate value for each location of the one or more locations at which a difference between the corresponding first and second voltage signals has a predetermined non-zero value, and assigning a FIT rate value of zero for each location of the one or more locations at which the difference between the corresponding first and second voltage signals is equal to zero. In some embodiments, calculating each FIT rate of the one or more FIT rates includes the corresponding first and second voltage signals comprising an AC voltage signal. In some embodiments, calculating each FIT rate of the one or more FIT rates includes identifying a plurality of AC stress states corresponding to a plurality of voltage levels of the AC voltage signal, assigning a predetermined scaling factor for each AC stress state of the plurality of AC stress states corresponding to a voltage difference between the first and second voltage signals having a non-zero value, and assigning a FIT rate value of zero for each AC stress state of the plurality of AC stress states corresponding to the difference between the corresponding first and second voltage signals having a zero value. In some embodiments, assigning the predetermined scaling factor for each AC stress state of the plurality of AC stress states includes assigning a rating factor corresponding to a duty cycle of the AC voltage signal. In some embodiments, the TDDB failure mechanism is a first TDDB failure mechanism of a plurality of TDDB failure mechanisms in the IC cell, the method includes, for each additional TDDB failure mechanism of the plurality of TDDB failure mechanisms, identifying one or more additional locations of the additional TDDB failure mechanism in the IC cell, wherein each additional location of the one or more additional locations includes third and fourth conductor features separated by an additional dielectric region, identifying third and fourth nets comprising the respective third and fourth conductor features, for each additional location of the one or more additional locations, calculating a corresponding additional FIT rate of a corresponding one or more additional FIT rates based on respective third and fourth voltage signals of the third and fourth nets, and calculating the total FIT rate includes, for each TDDB failure mechanism of the plurality of TDDB failure mechanisms, calculating a TDDB failure mechanism FIT rate by performing a first summing operation on each FIT rate of the one or more FIT rates or each additional FIT rate of the one or more additional FIT rates, and performing a second summing operation on the corresponding plurality of TDDB failure mechanism FIT rates. In some embodiments, performing the second summing operation on the plurality of TDDB failure mechanism FIT rates includes summing a term based on a correlation between multiple TDDB failure mechanisms of the plurality of TDDB failure mechanisms. In some embodiments, the method includes identifying failure information corresponding to a location of the one or more locations at which a FIT rate of the one or more FIT rates exceeds a threshold level, wherein modifying the IC cell is based on the failure location.

In some embodiments, a method includes for each cell of a plurality of cells in an IC layout diagram and each TDDB failure mechanism of a plurality of TDDB failure mechanisms, identifying one or more locations of the TDDB failure mechanism in the cell, wherein each location of the one or more locations includes first and second conductor features separated by a dielectric region, identifying first and second nets including the respective first and second conductor features, and for each location of the one or more locations, calculating a corresponding FIT rate of a corresponding one or more FIT rates based on respective first and second voltage signals of the first and second nets, calculating a total FIT rate of the IC layout diagram based on the one or more FIT rates of each TDDB failure mechanism of the plurality of TDDB failure mechanisms and each cell of the plurality of cells, and based on the total FIT rate, either modifying the IC layout diagram or storing the IC layout diagram in a storage device. In some embodiments, calculating each FIT rate of the one or more FIT rates of each TDDB failure mechanism of the plurality of TDDB failure mechanisms and each cell of the plurality of cells includes obtaining each of the corresponding first and second voltage signals from a simulation of a circuit corresponding to the IC layout diagram. In some embodiments, calculating the total FIT rate of the IC layout diagram includes calculating cell FIT rates by, for each cell of the plurality of cells, performing a first summing operation on each FIT rate of the one or more FIT rates of each TDDB failure mechanism of the plurality of TDDB failure mechanisms, and performing a second summing operation on the cell FIT rates corresponding to the plurality of cells. In some embodiments, performing the first summing operation includes summing a term based on a correlation between first and second TDDB failure mechanisms of the plurality of TDDB failure mechanisms. In some embodiments, calculating the cell FIT rates by performing the first summing operation for each cell of the plurality of cells includes calculating the corresponding one or more FIT rates based on one or more of a distribution of voltage levels between cells, a distribution of voltage levels over time, a distribution of temperatures between cells, or a distribution of temperatures over time. In some embodiments, calculating the total FIT rate of the IC layout diagram includes calculating TDDB failure mechanism FIT rates by, for each TDDB failure mechanism of the plurality of TDDB failure mechanisms, performing a first summing operation on each FIT rate of the one or more FIT rates of each cell of the plurality of cells, and performing a second summing operation on the TDDB failure mechanism FIT rates corresponding to the plurality of TDDB failure mechanisms. In some embodiments, calculating the TDDB failure mechanism FIT rates by performing the first summing operation for each TDDB failure mechanism of the plurality of TDDB failure mechanisms includes calculating the corresponding one or more FIT rates based on one or more of a distribution of voltage levels between cells, a distribution of voltage levels over time, a distribution of temperatures between cells, or a distribution of temperatures over time.

In some embodiments, an IC design system includes a processor and a non-transitory, computer readable storage medium including computer program code for one or more programs. The non-transitory, computer readable storage medium and the computer program code are configured to, with the processor, cause the processor to, for each cell of a plurality of cells in an IC layout diagram and each TDDB failure mechanism of a plurality of TDDB failure mechanisms, identify one or more locations of the TDDB failure mechanism in the cell, wherein each location of the one or more locations includes first and second conductor features separated by a dielectric region, identify first and second nets including the respective first and second conductor features, and for each location of the one or more locations, calculate a corresponding FIT rate of a corresponding one or more FIT rates based on respective first and second voltage signals of the first and second nets, calculate a total FIT rate of the IC layout diagram based on the one or more FIT rates of each TDDB failure mechanism of the plurality of TDDB failure mechanisms and each cell of the plurality of cells, based on the total FIT rate exceeding a first threshold level, identify a failure location at which a FIT rate of each TDDB failure mechanism of the plurality of TDDB failure mechanisms and each cell of the plurality of cells exceeds a second threshold level, and modify the IC layout diagram based on the failure location. In some embodiments, the non-transitory, computer readable storage medium and the computer program code are configured to, with the processor, cause the processor to modify the IC layout diagram by replacing a cell of the plurality of cells that comprises the failure location. In some embodiments, the non-transitory, computer readable storage medium and the computer program code are configured to, with the processor, cause the processor to modify the IC layout diagram by modifying a cell of the plurality of cells that comprises the failure location.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
identifying one or more locations of a time-dependent dielectric breakdown (TDDB) failure mechanism in an integrated circuit (IC) cell, wherein each location of the one or more locations comprises first and second conductor features separated by a dielectric region;
identifying first and second nets comprising the respective first and second conductor features;
for each location of the one or more locations, calculating a corresponding failure-in-time (FIT) rate of a corresponding one or more FIT rates based on respective first and second voltage signals of the first and second nets;
calculating a total FIT rate based on the one or more FIT rates; and
based on the total FIT rate, either modifying the IC cell or storing the IC cell in a storage device.

2. The method of claim 1, wherein the calculating each FIT rate of the one or more FIT rates comprises obtaining each of the corresponding first and second voltage signals from a simulation of a circuit comprising the first and second nets.

3. The method of claim 1, wherein the calculating each FIT rate of the one or more FIT rates comprises each of the corresponding first and second voltage signals being a direct current (DC) voltage signal.

4. The method of claim 3, wherein the calculating each FIT rate of the one or more FIT rates further comprises:
assigning a predetermined FIT rate value for each location of the one or more locations at which a difference between the corresponding first and second voltage signals has a predetermined non-zero value; and
assigning a FIT rate value of zero for each location of the one or more locations at which the difference between the corresponding first and second voltage signals is equal to zero.

5. The method of claim 1, wherein the calculating each FIT rate of the one or more FIT rates comprises the corresponding first and second voltage signals comprising an alternating current (AC) voltage signal.

6. The method of claim 5, wherein the calculating each FIT rate of the one or more FIT rates further comprises:
identifying a plurality of AC stress states corresponding to a plurality of voltage levels of the AC voltage signal;
assigning a predetermined scaling factor for each AC stress state of the plurality of AC stress states corresponding to a voltage difference between the first and second voltage signals having a non-zero value; and
assigning a FIT rate value of zero for each AC stress state of the plurality of AC stress states corresponding to the difference between the corresponding first and second voltage signals having a zero value.

7. The method of claim 6, wherein the assigning the predetermined scaling factor for each AC stress state of the plurality of AC stress states comprises assigning a rating factor corresponding to a duty cycle of the AC voltage signal.

8. The method of claim 1, wherein
the TDDB failure mechanism is a first TDDB failure mechanism of a plurality of TDDB failure mechanisms in the IC cell,
the method further comprises:
for each additional TDDB failure mechanism of the plurality of TDDB failure mechanisms:
identifying one or more additional locations of the additional TDDB failure mechanism in the IC cell, wherein each additional location of the one or more additional locations comprises third and fourth conductor features separated by an additional dielectric region;
identifying third and fourth nets comprising the respective third and fourth conductor features;
for each additional location of the one or more additional locations, calculating a corresponding additional FIT rate of a corresponding one or more additional FIT rates based on respective third and fourth voltage signals of the third and fourth nets, and
calculating the total FIT rate comprises:
for each TDDB failure mechanism of the plurality of TDDB failure mechanisms, calculating a TDDB failure mechanism FIT rate by performing a first summing operation on each FIT rate of the one or more FIT rates or each additional FIT rate of the one or more additional FIT rates; and
performing a second summing operation on the corresponding plurality of TDDB failure mechanism FIT rates.

9. The method of claim 8, wherein the performing the second summing operation on the plurality of TDDB failure mechanism FIT rates comprises summing a term based on a correlation between multiple TDDB failure mechanisms of the plurality of TDDB failure mechanisms.

10. The method of claim 1, further comprising:
identifying failure information corresponding to a location of the one or more locations at which a FIT rate of the one or more FIT rates exceeds a threshold level,
wherein the modifying the IC cell is based on the failure location.

11. A method comprising:
for each cell of a plurality of cells in an integrated circuit (IC) layout diagram and each time-dependent dielectric breakdown (TDDB) failure mechanism of a plurality of TDDB failure mechanisms:
identifying one or more locations of the TDDB failure mechanism in the cell, wherein each location of the one or more locations comprises first and second conductor features separated by a dielectric region;
identifying first and second nets comprising the respective first and second conductor features; and
for each location of the one or more locations, calculating a corresponding failure-in-time (FIT) rate of a corresponding one or more FIT rates based on respective first and second voltage signals of the first and second nets;
calculating a total FIT rate of the IC layout diagram based on the one or more FIT rates of each TDDB failure mechanism of the plurality of TDDB failure mechanisms and each cell of the plurality of cells; and
based on the total FIT rate, either modifying the IC layout diagram or storing the IC layout diagram in a storage device.

12. The method of claim 11, wherein the calculating each FIT rate of the one or more FIT rates of each TDDB failure mechanism of the plurality of TDDB failure mechanisms and each cell of the plurality of cells comprises obtaining each of the corresponding first and second voltage signals from a simulation of a circuit corresponding to the IC layout diagram.

13. The method of claim 11, wherein the calculating the total FIT rate of the IC layout diagram comprises:
calculating cell FIT rates by, for each cell of the plurality of cells, performing a first summing operation on each FIT rate of the one or more FIT rates of each TDDB failure mechanism of the plurality of TDDB failure mechanisms; and
performing a second summing operation on the cell FIT rates corresponding to the plurality of cells.

14. The method of claim 13, wherein the performing the first summing operation comprises summing a term based on a correlation between first and second TDDB failure mechanisms of the plurality of TDDB failure mechanisms.

15. The method of claim 13, wherein the calculating the cell FIT rates by performing the first summing operation for each cell of the plurality of cells comprises calculating the corresponding one or more FIT rates based on one or more of
a distribution of voltage levels between cells,
a distribution of voltage levels over time,
a distribution of temperatures between cells, or
a distribution of temperatures over time.

16. The method of claim 11, wherein the calculating the total FIT rate of the IC layout diagram comprises:
calculating TDDB failure mechanism FIT rates by, for each TDDB failure mechanism of the plurality of TDDB failure mechanisms, performing a first summing operation on each FIT rate of the one or more FIT rates of each cell of the plurality of cells; and
performing a second summing operation on the TDDB failure mechanism FIT rates corresponding to the plurality of TDDB failure mechanisms.

17. The method of claim 16, wherein the calculating the TDDB failure mechanism FIT rates by performing the first summing operation for each TDDB failure mechanism of the plurality of TDDB failure mechanisms comprises calculating the corresponding one or more FIT rates based on one or more of
a distribution of voltage levels between cells,
a distribution of voltage levels over time,
a distribution of temperatures between cells, or
a distribution of temperatures over time.

18. An integrated circuit (IC) design system comprising:
a processor; and
a non-transitory, computer readable storage medium including computer program code for one or more programs, the non-transitory, computer readable storage medium and the computer program code being configured to, with the processor, cause the processor to:
for each cell of a plurality of cells in an IC layout diagram and each time-dependent dielectric breakdown (TDDB) failure mechanism of a plurality of TDDB failure mechanisms:
identify one or more locations of the TDDB failure mechanism in the cell, wherein each location of the one or more locations comprises first and second conductor features separated by a dielectric region;
identify first and second nets comprising the respective first and second conductor features; and
for each location of the one or more locations, calculate a corresponding failure-in-time (FIT) rate of a corresponding one or more FIT rates based on respective first and second voltage signals of the first and second nets;
calculate a total FIT rate of the IC layout diagram based on the one or more FIT rates of each TDDB failure mechanism of the plurality of TDDB failure mechanisms and each cell of the plurality of cells;
based on the total FIT rate exceeding a first threshold level, identify a failure location at which a FIT rate of each TDDB failure mechanism of the plurality of TDDB failure mechanisms and each cell of the plurality of cells exceeds a second threshold level; and
modify the IC layout diagram based on the failure location.

19. The IC design system of claim 18, wherein the non-transitory, computer readable storage medium and the computer program code are configured to, with the processor, cause the processor to modify the IC layout diagram by replacing a cell of the plurality of cells that comprises the failure location.

20. The IC design system of claim 18, wherein the non-transitory, computer readable storage medium and the computer program code are configured to, with the processor, cause the processor to modify the IC layout diagram by modifying a cell of the plurality of cells that comprises the failure location.
